(19) United States
(12) Patent Application Publication
(10) Pub. No.: US 2001/0033180 A1
(43) Pub. Date: Oct. 25, 2001

(54) TEST PIN WITH REMOVABLE HEAD

(76) Inventors: MARK A. SWART, ANAHEIM HILLS, CA (US); GORDON A. VINTHER, ONTARIO, CA (US)

Correspondence Address: CHRISTIE PARKER & HALE, PO BOX 7068, PASADENA, CA, 911097068

(21) Appl. No.: 09/007,352

(22) Filed: Jan. 15, 1998

(51) Int. Cl. G01R 31/02

(52) U.S. Cl. 324/761

(57) ABSTRACT

A translator pin having a body portion and a removable head portion positioned at one end of the body portion. The head includes a channel extending into the head for receipt of the body portion to provide a friction fit between the head the body portion. The channel may include detents to provide frictional engagement with the body portion of the translator pin.

### FIELD OF THE INVENTION

This invention relates to the automatic testing of printed circuit boards, and more particularly, to a test pin with a removable head for a translator fixture for translating test signals from a board under test to a pattern of test probes in a tester. The invention has to do with improvements in the construction of the test pins.

### BACKGROUND OF THE INVENTION

Automatic test equipment for checking printed circuit boards has long involved use of a “bed of nails” test fixture in which the circuit board is mounted during testing. This test fixture includes a large number of nail-like spring-loaded test probes arranged to make electrical contact under spring pressure with designated test points on the circuit board under test, also referred to as the unit under test or “UUT.” Any particular circuit laid out on a printed circuit board is likely to be different from other circuits, and consequently, the bed of nails arrangement for contacting test points in the board must be customized for that particular circuit board. When the circuit to be tested is designed, a pattern of test points to be used in checking it is selected, and a corresponding array of test probes is configured in the test fixture. This typically involves drilling a pattern of holes in a probe plate to match the customized array of test probes and then mounting the test probes in the drilled holes on the probe plate. The circuit board is then mounted in the fixture superimposed on the array of test probes. During testing, the spring-loaded probes are brought into spring-pressure contact with the test points on the circuit board under test. Electrical test signals are then transferred from the board to the test probes and then to the exterior of the fixture for communication with a high speed electronic test analyzer which detects continuity or lack of continuity between various test points in the circuits on the board.

Various approaches have been used in the past for bringing the test probes and the circuit board under test into pressure contact for testing. One class of these fixtures is a “wired test fixture” in which the test probes are individually wired to separate interface contacts for use in transmitting test signals from the probes to the external electronically controlled test analyzer. These wired test fixtures are often referred to as “vacuum test fixtures” since a vacuum is applied to the interior of the test fixture housing during testing to compress the circuit board into contact with the test probes. Customized wired test fixtures of similar construction also can be made by using mechanical means other than vacuum to apply the spring force necessary for compressing the board into contact with the probes during testing.

The wire-wrapping or other connection of test probes, interface pins and transfer pins for use in a wired test fixture can be time intensive. However, customized wired test fixtures are particularly useful in testing circuit boards with complex arrangements of test points and low-volume production boards where larger and more complex and expensive electronic test analyzers are not practical.

As mentioned previously, the customized wired test fixtures are one class of fixtures for transmitting signals from the fixture to the external circuit tester. A further class of test fixtures is the so called “dedicated” test fixtures, also known as a “grid-type fixture,” in which the random pattern of test points on the board are contacted by translator pins which transfer test signals to interface pins arranged in a grid pattern in a receiver. In these grid-type testers, fixturing is generally less complex and simpler than in the customized wired test fixtures.

A typical dedicated or grid fixture contains test electronics with a huge number of switches connecting test probes in a grid base to corresponding test circuits in the electronic test analyzer. In one embodiment of a grid tester as many as 40,000 switches are used. When testing a bare board on such a tester, a translator fixture supports translator pins that communicate between a grid pattern of test probes in a grid base and an off-grid pattern of test points on the board under test. In one prior art grid fixture so-called tilt pins are used as the translator pins. The tilt pins are straight pins mounted in corresponding pre-drilled holes in translator plates which are part of the translator fixture. The tilt pins can tilt in various orientations to translate separate test signals from the off-grid random pattern of test points on the board to the grid pattern of test probes in the grid base.

In the past, tilt pins required an enlarged head when used to test sites such as a via on a circuit board. To accommodate an enlarged head the tilt pins were manufactured as an integral unit by milling the body portion of the pin to reduce its diameter. Alternatively the body of the pin was drawn as a hollow tube and a separate head portion was manufactured with a tail which was forced under pressure into the hollow tube. These type of translator pins are undesirable since they are expensive to manufacture and are less versatile. Tubular bodies also require the pins to have a larger diameter which requires bigger holes in the fixture. Larger fixture holes limits the number of pins that can be used in the fixture and also reduces the accuracy of the tilt pins. This is especially undesirable when the unit under test has many closely spaced test points. Larger diameter tilt pins also reduces the angle at which the pins can tilt. Another disadvantage of this design is that since the heads of the pins could not be removed, a separate inventory was required.

Consequently a need exists for a new leaded translator pin design which reduces the problems associated with prior designs, is easy and inexpensive to manufacture, and is reusable without the head.

### SUMMARY OF THE INVENTION

Briefly, one embodiment of this invention comprises a test or tilt pin for a translator fixture for a printed circuit board tester of the type having a pattern of test probes on a base upon which the translator fixture is mounted. The translator fixture comprises a plurality of essentially parallel and vertically spaced apart rigid translator plates having selected patterns of pre-drilled holes for supporting the tilt or translator pins for contacting test points on a printed circuit board supported on one side of the translator fixture. The translator pins translate electrical test signals between test points on the printed circuit board and the test probes at the base of the tester. The tilt pin comprises a standard 20 mil tilt pin and a removable head positioned over one end of the tilt pin. The removable head has a contact end for contacting the test site and a hollow receiving end which is positioned over the end of the tilt pin. The receiving end has detents or other engaging surfaces to retain the head on the tilt pin, yet allows easy removal of the head.

These and other aspects of the invention will be more fully understood by referring to the following detailed description and the accompanying drawings.

### BRIEF DESCRIPTION OF THE DRAWINGS

FIG. 1 is a schematic block diagram illustrating components of a dedicated or grid type tester and a translator fixture constructed and assembled according to principles of this invention.

FIG. 2. is a cross-sectional side view of the tilt pin of the present invention.

FIG. 3 is a cross-sectional side view of an alternative head design of the tilt pin of FIG. 2.

### DETAILED DESCRIPTION

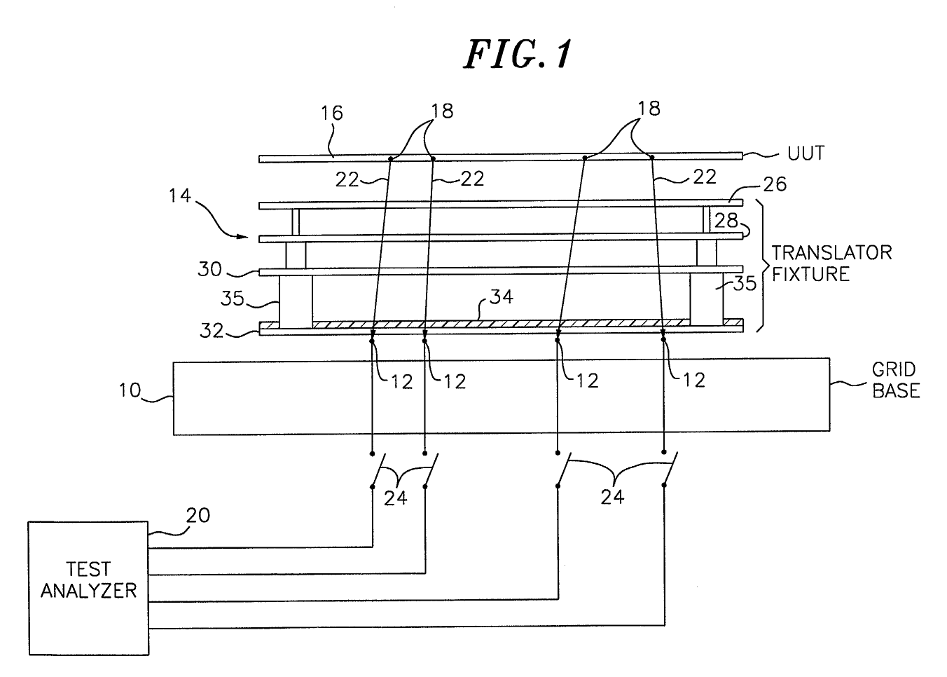

Referring to the schematic block diagram of FIG. 1, a grid-type printed circuit board tester includes a grid base 10 having an array of spring-loaded test probes 12 arranged on a two-dimensional grid pattern. The test probes illustrated schematically in FIG. 1 preferably comprise an orthogonal array of uniformly spaced-apart rows and columns of test probes which may be aligned on 100 mil centers as an example. The spring-loaded plungers of the test probes 12 project above the surface of the grid base uniformly across the array of probes. A translator fixture 14 supports a printed circuit board 16 under test (also referred to as a “unit under test” or “UUT”) . The translator fixture serves as an interface between an array of test points 18 on the board under test and the test probes 12 in the grid base 10. An external electronic test analyzer 20 is electrically connected to the test points in the board under test through test probes or pins commonly referred to as tilt pins or translator pins in the translator fixture. These test probes are illustrated generally at 22.

The test analyzer 20 contains electronic interrogation circuits to electronically interrogate separate test points 18 of the board under test in order to determine whether or not an electrical connection exists between any two given test points. The electrical connections detected between test points on the tested board are electronically compared with stored reference results obtained from a previous interrogation of test points of a faultless master printed circuit board. The tested board is good if test results match the stored reference results, but if any problem exists in the circuits on the board, the problem is detected by the test results and the bad boards then can be separated from the good boards.

Electronic interrogation circuits in one embodiment comprise the plurality of printed circuit cards (sometimes called “switch cards”) having electronic components and printed circuits for carrying out the electronic testing. Each test probe used in the test procedure is represented as being coupled to the test electronics through a corresponding switch 24 leading to the test analyzer. In a given grid-type tester there can be as many as 40,000 switches available for testing the various test points in a board under test.

A typical translator fixture is described in detail in applicant's U.S. patent application Ser. No. 08/531,720 filed Sep. 21, 1995, the disclosure of which is incorporated herein by reference. In general, translator fixture 14 includes a series of vertically spaced apart and parallel translator plates which may include a top plate 26, an upper plate 28 spaced a short distance below the top plate, a lower plate 30 at approximately an intermediate level of the translator fixture, and a base plate 32 at the bottom of the translator fixture. The translator plates are supported in parallel vertically spaced apart positions by rigid, integral stair-step posts 35 (also referred to as stacking towers) that hold the fixture together as a rigid unit. FIG. 1 illustrates use of four translator plates in the translator fixture, however a larger number of translator plates are more commonly used.

The translator fixture also includes an array of standard 20 mil translator pins such as tilt pins (represented schematically at 22) extending through the translator plates 26, 28, 30 and 32. FIG. 1 illustrates only a few of the standard tilt pins for simplicity. The tilt pins extending through the base plate 32 of the translator fixture are in alignment with the grid pattern of test probes 12 in the grid base 10. The top portions of the tilt pins, which extend through the top plate 26, are in an off-grid pattern aligned to match the random pattern of test points 18 on the UUT. Thus, the tilt pins can be tilted slightly in various three dimensional orientations used to translate between the grid pattern at the base and the off-grid pattern at the top. The standard tilt pins pass through holes in the base plate, through holes in the lower and upper plates, and through a hole pattern in the top plate. The holes in each of the translator plates (represented by reference numerals 33) are drilled in mostly diagonal patterns and the drill patterns are controlled by standard computer-operated software according to well-known procedures. The translator pins are retained in the fixture by an elastomeric pin retention sheet 34.

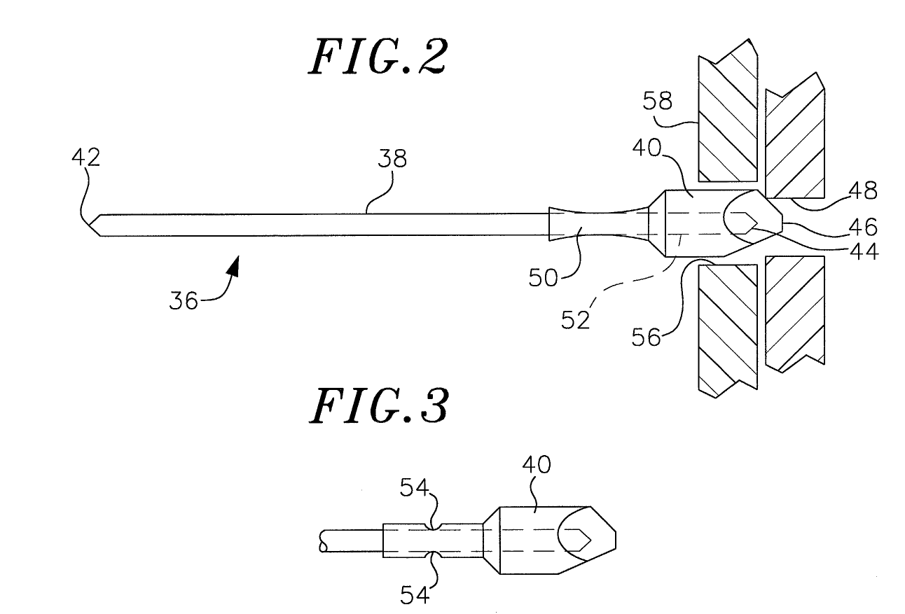

FIG. 2 illustrates the translator or tilt pin 36 of the present invention. Tilt pin 36 includes a body portion 38 and a removable head 40. Body portion 38 is a standard 20 mil translator pin having a first end 42 and a second end 44. Other sized pins can also be used by the invention. The head 40 is enlarged compared to body portion 38 and has a contact end 46 for contacting the test site 48 on the unit under test. The test site in this case is a via on the circuit board, however can be other types of test sites. The head also has a receiving end 50 opposite of end 46 for insertion of the body portion 38. Receiving end 50 has a channel 52 extending inwardly toward the contact end for receipt of second end 44 of body portion 38. The channel 52 can be curved to provide a friction fit between the head and the body of the translator pin, or can have detents 54 as shown in FIG. 3. The head passes through holes 56 in the translator top plate 58 to contact the test site. The diameter of the head and the shape of the contact end 46 can be varied according to the requirements of the test site.

The present invention allows for heads to be attached and removed as needed, thus making both the pin and the head reusable. The translator pin design also allows for the use of standard 20 mil pins thereby reducing the necessary inventory.

What is claimed is:

1. A translator pin comprising a body portion and a removable head portion positioned at one end of the body portion.

2. The pin of claim 1 wherein the body portion is a standard 20 mil pin.

3. The pin of claim 1 where in the head includes means for engaging the body portion.

4. The pin of claim 3 wherein the engaging means is a channel extending into the head for receipt of the body portion.

5. The pin of claim 4 wherein the channel is curved to provide a friction fit with the body portion.

6. The pin of claim 4 wherein the channel includes detents to engage the body portion.

7. For use in a translator fixture for a printed circuit board tester of the type having a pattern of test probes on a base upon which the translator fixture is mounted, the translator fixture comprising a plurality of essentially parallel and vertically spaced apart rigid translator plates supported in a fixed positioned in the translator fixture and having selected patterns of holes aligned in the translator plates for containing and supporting translator pins extending through the translator plates for positioning the translator pins for contacting test points on a printed circuit board supported in an essentially horizontal position at one end of the translator fixture, the translator pins translating electrical test signals between the test points on the printed circuit board and the test probes on the base of the tester, the improvement in which the translator fixture includes a plurality of removable heads for the translator pins, wherein the head include means for engaging the translator pins.

8. The fixture of claim 7 wherein the means for engaging the translator pins is a channel extending into the head for receipt of a body portion of the translator pin.

9. The fixture of claim 8 wherein the channel is curved to provide a friction fit with the body portion.

10. The fixture of claim 8 wherein the channel includes detents to engage the body portion.
